(19) United States
(12) Patent Application Publication
(10) Pub. No.: US 2017/0317106 A1
(43) Pub. Date: Nov. 2, 2017

(54) MOS TRANSISTOR STRUCTURE, IN PARTICULAR FOR HIGH VOLTAGES USING A TECHNOLOGY OF THE SILICON-ON-INSULATOR TYPE

(71) Applicants: STMicroelectronics (Rousset) SAS, Rousset (FR); STMicroelectronics (Crolles 2) SAS, Crolles (FR)

(72) Inventors: Philippe Boivin, Venelles (FR); Franck Arnaud, Nazaire Les Eymes (FR); Gregory Bidal, Grenoble (FR); Dominique Golanski, Gieres (FR); Emmanuel Richard, Saint Pierre D'allevard (FR)

(73) Assignees: STMicroelectronics (Rousset 2) SAS, Rousset (FR); STMicroelectronics (Crolles 2) SAS, Crolles (FR)

(21) Appl. No.: 15/361,937

(22) Filed: Nov. 28, 2016

(30) Foreign Application Priority Data
Apr. 27, 2016 (FR) 1653726

(51) Int. Cl. H01L 27/12; H01L 29/06; H01L 29/08; H01L 29/49

(52) U.S. Cl. CPC H01L 27/1207; H01L 29/4916; H01L 29/0653; H01L 29/0847

(57) ABSTRACT

An integrated circuit is formed using a substrate of a silicon-on-insulator type that includes a carrier substrate and a stack of a buried insulating layer and a semiconductor film on the carrier substrate. A first region without the stack separates a second region that includes the stack from a third region that also includes the stack. An MOS transistor has a gate dielectric region formed by a portion of the buried insulating layer in the second region and a gate region formed by a portion of the semiconductor film in the second region. The carrier substrate incorporates doped regions under the first region which form at least a part of a source region and drain region of the MOS transistor.

### PRIORITY CLAIM

This application claims the priority benefit of French Application for Patent No. 1653726, filed on Apr. 27, 2016, the disclosure of which is hereby incorporated by reference.

### TECHNICAL FIELD

Various embodiments relate to integrated circuits, notably the structures of MOS transistor formed on a substrate of the “silicon-on-insulator” type, commonly denoted by those skilled in the art under the acronym SOI, for example on a substrate of the “partially-depleted silicon-on-insulator” type, known by those skilled in the art under the acronym PDSOI, or else of the “fully-depleted silicon-on-insulator” type, known by those skilled in the art under the acronym FDSOI and, more particularly, the structures of MOS transistors formed on such substrates and capable of withstanding a high voltage, in other words a voltage higher than 1.8 volts, for example a voltage of 5 volts or more.

### BACKGROUND

A substrate of the silicon-on-insulator type comprises a semiconductor film, for example of silicon or of an alloy of silicon, situated on top of a buried insulating layer, commonly denoted using the acronym BOX (for Buried Oxide) itself situated on top of a carrier substrate, for example a semiconductor well.

In an FDSOI technology, the semiconductor film is fully depleted, in other words it is composed of intrinsic semiconductor material. Its thickness is generally a few nanometers. Furthermore, the buried insulating layer is itself generally thin, of the order of ten nanometers.

Currently, the MOS transistors formed using a technology of the SOI, in particular FDSOI, type conventionally comprise, as gate oxide, a material with a high dielectric constant K (“high K” material) for example hafnium-silicon oxynitride (HfSiON). The isolated gate region of the transistor furthermore comprises, for example on top of this layer of gate oxide, a metal multilayer itself covered by amorphous silicon.

Such transistors offer improved performance characteristics, notably in terms of speed and frequency.

However, in some applications, such as for example in non-volatile memories or high-voltage interfaces, it may be necessary to form transistors referred to as “high-voltage transistors”, in other words capable of withstanding high voltages. In an SOI technology, in particular FDSOI, a high voltage is typically a voltage generally higher than 1.8 volts. However, the materials of the “high K” type are not designed to operate at high voltage.

For this reason, currently, high-voltage MOS transistors cannot be fabricated using an SOI technology, in particular an FDSOI technology, without carrying out numerous specific additional operations.

### SUMMARY

According to one embodiment and its implementation, the idea is consequently to form an MOS transistor structure in a simple manner using an SOI, in particular FDSOI, technology which is capable of withstanding a high voltage, in other words a voltage typically higher than 1.8 volts, for example 5 volts.

According to one embodiment and its implementation, it is intended to form such a structure without degrading the other MOS transistors of the integrated circuit which are fabricated with regions of gate dielectric of the “high K” type.

The inventors have observed that, for this purpose, the buried insulating layer (BOX) of the substrate of the SOI type could advantageously be used as gate oxide of the MOS transistor structure, thus capable of withstanding a high voltage.

The threshold voltage of such an MOS transistor is adjusted by the thickness of the gate oxide, in other words by the thickness of the buried insulating layer.

According to one aspect, an integrated circuit is thus provided, comprising a substrate of the silicon-on-insulator type, in particular of the partially-depleted or fully-depleted silicon-on-insulator type, comprising a carrier substrate on top of which there is a stack of a buried insulating layer and of a semiconductor film.

According to a general feature of this aspect, the integrated circuit comprises at least a first region without the stack and separating a second region of the stack from a third region of the stack.

The integrated circuit then comprises at least one MOS transistor whose gate dielectric region comprises the portion of buried insulating layer of the second region of the stack and whose gate region comprises the portion of semiconductor film of the second region of the stack.

Furthermore, the carrier substrate incorporates at least a part of the source and drain regions of this transistor.

Various embodiments of such a MOS transistor structure are possible as will be described in more detail hereinafter.

However, whichever embodiment is used, the integrated circuit may also advantageously comprise, in addition, at least one other MOS transistor, advantageously an MOS transistor having a gate dielectric region comprising a material with a high dielectric constant, this other transistor being formed in and on the portion of semiconductor film situated within the third region of the stack.

### BRIEF DESCRIPTION OF THE DRAWINGS

Other advantages and features of the invention will become apparent upon examining the detailed description of non-limiting embodiments and from the appended drawings in which:

FIGS. 1 to 5 illustrate schematically various embodiments of an integrated circuit comprising a MOS transistor.

### DETAILED DESCRIPTION OF THE DRAWINGS

In the following embodiments, in certain cases NMOS transistors, and in of other cases PMOS transistors will be described. It goes without saying that what is described for a NMOS transistor may be applied in a reciprocal manner for a PMOS transistor and vice versa.

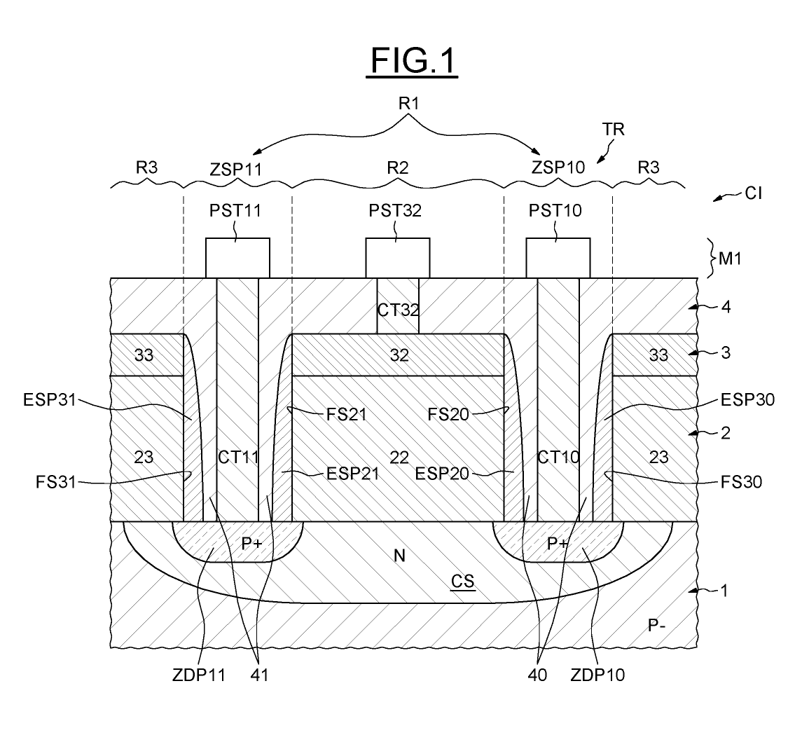

In FIG. 1, the reference CI denotes an integrated circuit comprising a substrate of the silicon-on-insulator type, for example of the fully-depleted silicon-on-insulator type, comprising an MOS transistor structure TR notably capable of operating at high voltage, for example 5 Volts. Conventionally, the transistor structure TR is laterally isolated by insulating regions, for example of the shallow trench isolation (or STI) type, not shown here for the sake of simplification of the figure.

The substrate of the SOI or FDSOI type comprises a carrier substrate 1, for example a substrate of P⁻-doped silicon, on top of which is a stack comprising a buried insulating layer 2 (BOX) and a semiconductor film 3, for example of silicon.

Depending on the technology used, of the SOI or FDSOI type, the thickness of the buried insulating layer can vary as can the thickness of the semiconductor film 3.

Thus, by way of example, the thickness of the buried insulating layer 2 can be in the range between around 12 nm and around 100 nm, whereas the thickness of the semiconductor film can be in the range between around 7 nm and around 100 nm.

As illustrated in FIG. 1, the integrated circuit here comprises a first region R1 that does not include the stack of the buried insulating layer 2 (BOX) and semiconductor film 3.

In the example in FIG. 1, this first region R1 comprises two separation regions ZSP10 and ZSP11.

The first region R1 thus separates a second region R2 from a third region R3, wherein both the second region R2 and third region R3 include the stack of the buried insulating layer 2 (BOX) and semiconductor film 3.

More precisely, in the example in FIG. 1, the two separation regions ZSP10 and ZSP11 respectively separate two faces of the second region R2 of the stack from two faces of the third region of the stack.

Thus, the separation region ZSP10 separates the face FS20 of the second region of the stack from the face FS30 of the third region of the stack, whereas the separation region ZSP11 separates the face FS21 of the second region of the stack from the face FS31 of the third region of the stack.

Thus, the second region R2 of the stack comprises a portion 22 of buried insulating layer 2 and a portion 32 of semiconductor film 3. The region of dielectric of the MOS transistor TR comprises the portion 22 of buried insulating layer and the gate region of the transistor TR comprises the portion 32 of semiconductor film.

The third region R3 of the stack comprises a portion 23 of buried insulating layer 2 and a portion 33 of semiconductor film 3.

The width of each separation region, in other words the distance between the two faces of the stack facing one another, can vary between 80 and 300 nm depending on the technological node used.

The source and drain regions of the transistor TR comprise doped regions ZDP10 and ZDP11 situated within the carrier substrate 1 respectively facing the two separation regions ZSP10 and ZSP11.

In the example described here, since the transistor TR is a PMOS transistor, the doped regions ZDP10 and ZDP11 are P⁺-doped regions situated within a semiconductor well CS, of the N type of conductivity, situated, in part, under the dielectric region 22 of the transistor TR.

Furthermore, each separation region comprises:

an electrically-conducting region coming into contact with the doped region of the corresponding source or drain region, and

an insulating region disposed between this electrically-conducting region and the corresponding faces of the second region and of the third region of the stack.

More precisely, in the example illustrated in FIG. 1, each electrically-conducting region comprises an electrically-conducting contact CT10 (CT11), for example made of tungsten, coming into contact, via a silicided region (not shown here for the sake of simplification) with the doped source or drain region ZDP10 (ZDP11). The contact CT10 (CT11) extends as far as the first metallization level M1 of the integrated circuit so as to come for example into contact with a metal track PST10 (PST11).

With regard to the insulating region disposed between each contact and the corresponding faces FS21, FS20 of the second region and the faces FS30 and FS31 of the third region, here it comprises spacers ESP20, ESP30, ESP30, ESP31 situated, as far as the separation region ZSP10 is concerned, on the faces FS20 and FS30, respectively, and as far as the separation region ZSP11 is concerned, on the faces FS31 and FS21, respectively. These spacers are formed by conventional steps of a CMOS fabrication process.

Furthermore, the insulating regions also comprise a portion 40, 41 of a layer of dielectric material 4, known by those skilled in the art under the acronym PMD (for Pre-Metal Dielectric), which extends as far as the first metallization level M1. The transistor TR also comprises a gate contact CT32 coming into contact with the portion 32 of semiconductor film and extending as far as a metal track PST32 of the metallization level M1.

Here again, the silicided region on which the contact CT32 is placed has not been shown for the sake of simplification.

Depending on the technological node used, and depending on the thickness of the film 3, it may be necessary, prior to the formation of the contact CT32, to increase the thickness of the film 32 by a localized re-epitaxy followed by a silicidation so as to avoid the contact CT32 going through the gate semiconductor region 32.

This is notably the case for a 14 nm FDSOI technology.

If it is provided in the CMOS process, it is possible to also carry out a localized re-epitaxy followed by a silicidation of the doped source or drain regions ZDP10 (ZDP11). However, this is in no way obligatory.

The fabrication of such a transistor TR is carried out for example by using conventional CMOS fabrication process steps.

Thus, in a 28 nm technological node, after having defined the isolation regions in the wafer of the SOI type, for example of the shallow trench isolation (STI) type, the various N and P wells are conventionally formed by implantation.

Then, a conventional etch process is carried out to remove the stack—BOX 2 and semiconductor film 3—in the separation regions ZSP10 and ZSP11.

Then, the standard formation of the insulating spacers, included in the CMOS process, is carried out typically by conformal deposition of silicon dioxide for example, and anisotropic etching.

The layer of dielectric material 4 is subsequently deposited and, after localized etching so as to form, within this layer 4, the orifices designed to receive the contacts CT10, CT11 and CT32, these orifices are then filled by metal, for example tungsten.

The order of these steps may be modified depending on the technological node. Thus, in a more advanced technological node, for example 14 nm, the step for local etching of the stack—BOX 2 and semiconductor film 3—may be carried out prior to the etching of the isolation trenches of the STI type.

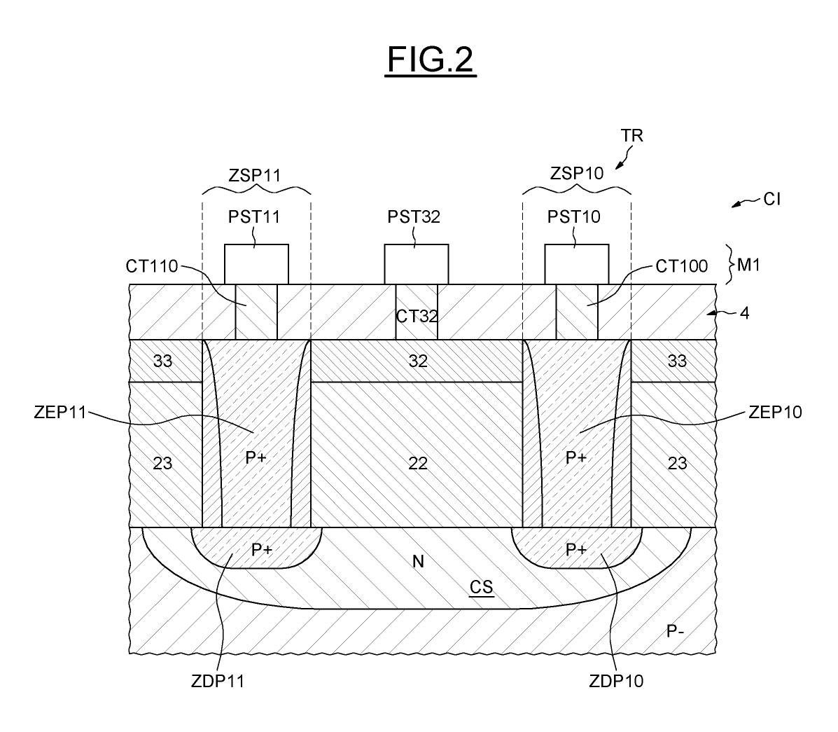

In one variant embodiment illustrated in FIG. 2, the electrically-conducting region that comes into contact with the doped regions ZDP10 and ZDP11 may comprise an epitaxied region ZEP10, ZEP11, for example in the present case Ptdoped, filling the separation regions ZSP10 and ZSP11 between the insulating spacers.

The contacts CT100, CT110 then come into contact with the silicided regions (not shown for the sake of simplification) of these epitaxied regions ZEP10 and ZEP11, and extend into the layer of dielectric 4 as far as the corresponding metal tracks of the metallization level M1.

In the embodiment in FIG. 2, in certain cases, there may exist a risk of short-circuit between the epitaxied regions ZEP10 and ZEP11 and the neighbouring semiconductor film 32 or 33.

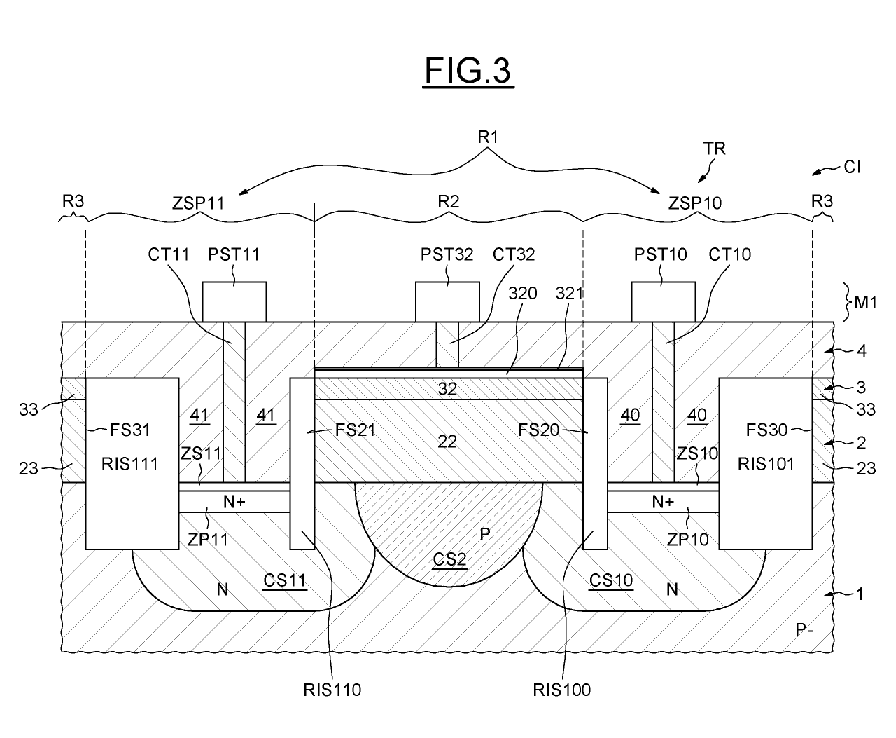

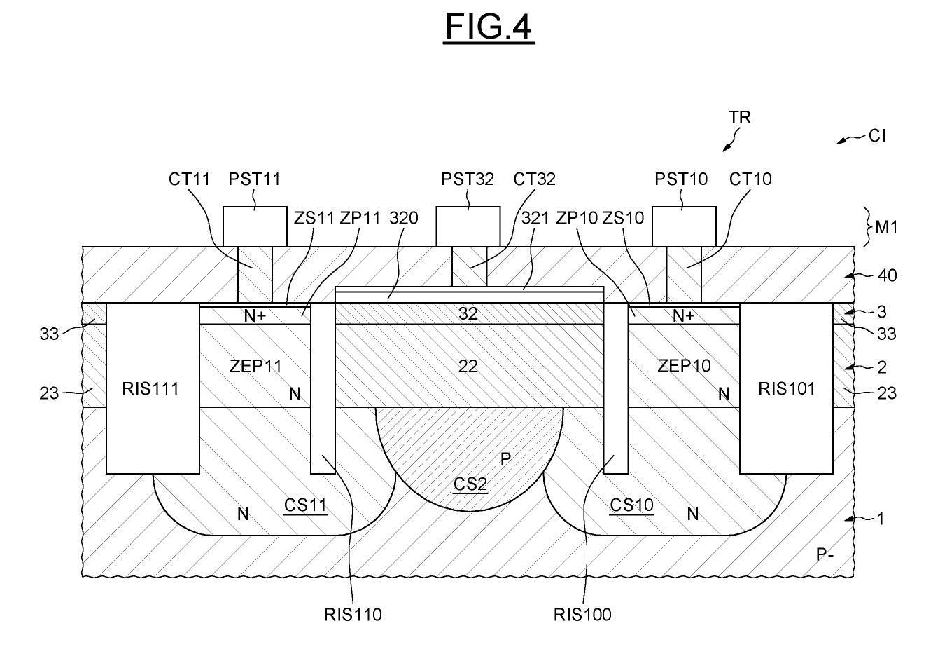

In order to avoid such a risk of short-circuit, the use of the embodiment illustrated in FIG. 3 or that illustrated in FIG. 4 is provided.

In FIG. 3, the elements analogous to the elements illustrated in FIG. 1 have identical references to those in FIG. 1. Only the differences between FIG. 1 and FIG. 3 will now be described.

In the embodiment in FIG. 3, each separation region comprises a first isolation trench in contact with a first face of the second region of the stack, this first isolation trench extending into the carrier substrate.

Each separation region also comprises a second isolation trench in contact with a first face of the third region of the stack, this second isolation trench also extending into the carrier substrate.

More precisely, the separation region ZSP10 comprises a first isolation trench RIS100, for example of the shallow isolation trench type (STI), in contact with the first face FS20 of the second region R2 of the stack 22, 32, this first isolation trench RIS100 extending into the carrier substrate.

The separation region ZSP10 also comprises the second isolation trench RIS101, also for example of the shallow isolation trench type, in contact with the first face FS30 of the third region R3 of the stack 23, 33, this second isolation trench RIS101 also extending into the carrier substrate 1.

The separation region ZSP11 also comprises a first isolation trench RIS110 in contact with a first face FS21 of the second region R2 of the stack 22, 32, this first isolation trench RIS110 also extending into the carrier substrate 1.

The separation region ZSP11 also comprises a second isolation trench RIS111 in contact with a first face FS31 of the third region R3 of the stack 23, 33, this second isolation trench RIS111 also extending into the carrier substrate 1.

Furthermore, here again, the source and drain regions of the transistor comprise doped regions situated within the carrier substrate 1 respectively facing the two separation regions ZSP10 and ZSP11.

However, in this embodiment, the doped region of the corresponding source or drain region also extends, in part, into the region of carrier substrate situated under the gate dielectric region 22 of the transistor.

More precisely, since in the presence of a transistor TR of the NMOS type, one of the source or drain regions of the transistor here comprises a well CS10, of the N type of conductivity, situated within the carrier substrate 1 and extending facing the separation region ZSP10 and also facing the right-hand part of the dielectric region 22 of the transistor TR.

This source or drain region also comprises a more highly doped region ZP10, of the N⁺ type, together with a silicided region ZS10.

The other one of the source or drain regions comprises, by analogy, a semiconductor well CS11 of the N type of conductivity extending facing the separation region ZSP11 and also facing the left-hand part of the region of dielectric 22 of the transistor TR.

Here again, this other source or drain region comprises a more highly doped region ZP11, of the N⁺ type, together with a silicided region ZS11.

Here, the transistor TR also comprises a well CS2, of the P type of conductivity, hence more highly doped than the carrier substrate 1, this well CS2 being situated between the wells CS10 and CS11.

In the embodiment illustrated in FIG. 3, the silicided regions ZS10 and ZS11 are electrically connected to the metal tracks PST10 and PST11 of the metallization level M1 by the two metal contacts CT10 and CT11 coated in the dielectric material 4, and notably the portions 40 and 41 of this dielectric material 4.

In the example described here, in which the semiconductor film 32 is particularly thin, as explained hereinbefore, the re-epitaxied region of silicon 320 is shown covered by a silicided region 321 onto which comes the gate metal contact CT32.

It should be noted that, in this case, a good isolation is obtained between the gate 32 of transistor TR and the source or drain regions by virtue of the isolation regions RIS100 and RIS110, advantageously of the trench type, which can for example have a width of the order of 50 nm.

Furthermore, a high resistivity current passage is obtained between the channel region and the source or drain regions of the transistor by virtue of the presence of the insulating regions RIS110 and RIS100 which penetrate into the wells CS10 and CS11 and thanks to the lateral diffusion of the implanted wells CS10 and CS11.

Furthermore, this resistivity may be modulated by acting on the width of the insulating regions RIS110 and RIS100.

By analogy with what has been described with reference to FIG. 2, it is possible, as illustrated in FIG. 4, to provide an embodiment of the transistor TR in which the lower part of the contact CT10 (CT11) is replaced by an additional semiconductor region ZEP10 (ZEP11) obtained by re-epitaxy starting from the well CS10 (CS11). The upper part of this epitaxied region ZEP10 (ZEP11) comprises an over-doped region ZP10 (ZP11), itself covered by the silicided region ZS10 (ZS11). In the example described here, the regions ZEP10, ZP10, ZEP11, ZP11 have the N type of conductivity.

Here again, by analogy with FIG. 2, if included in the CMOS process, it is possible to also perform a localized re-epitaxy followed by a silicidation of the doped source or drain regions ZEP10 and ZEP11. However, this is in no way obligatory.

Short-circuiting between the upper part of the region ZEP10 and ZEP11 and the semiconductor film 32 or 33 is furthermore avoided by the presence of the insulating regions RIS100 and RIS110, or RIS101 and RIS111, advantageously of the trench type.

Here again, the steps for fabrication of such a transistor TR are conventional fabrication steps of a CMOS process and essentially the same type of step is used as that described for the fabrication of the transistor TR in FIG. 1, except for the steps relating to the formation of the spacers ESP.

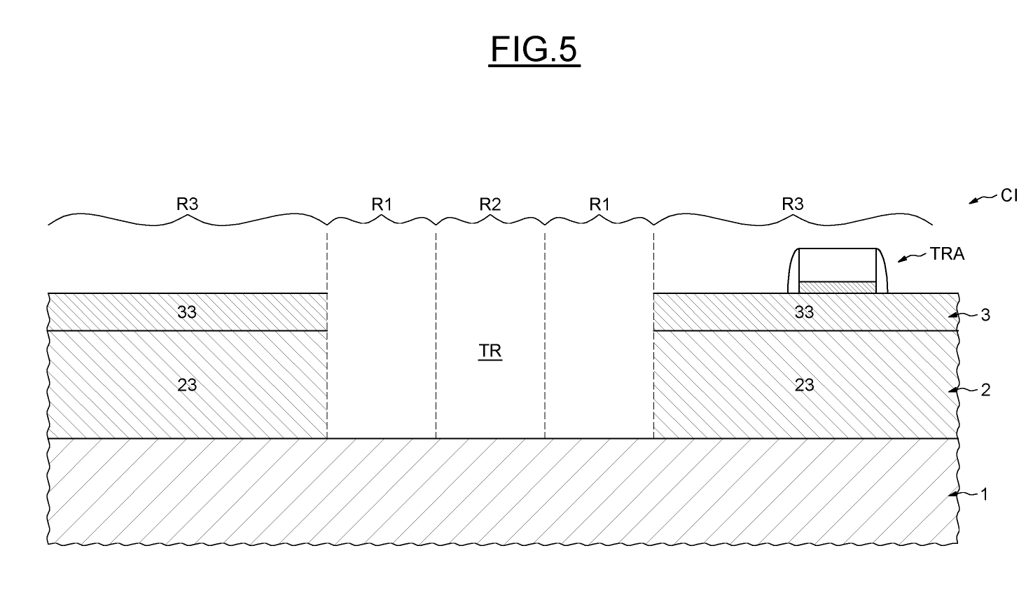

In FIG. 5, the integrated circuit CI furthermore comprises at least one other MOS transistor TRA formed in and on the portion 33 of semiconductor film situated in the third region R3 of the stack, this other transistor TRA having a gate dielectric region comprising a material with a high dielectric constant.

Moreover, this embodiment is of course compatible irrespective of the structure of the MOS transistor TR formed in the region R2 of the stack.

Furthermore, the high-voltage MOS transistor structure TR and its method of fabrication are perfectly compatible with the method of fabrication used for the formation of transistors of the TRA type with a gate dielectric region comprising a “high K” material. Indeed, after depositing the layer of “high K” dielectric material over the whole of the wafer, by using a suitable mask, this layer of “high K” material just needs to be eliminated in the regions R1 and R2 in order to be able to carry out the fabrication of the transistor TR with the usual steps for etching the gates which will not degrade the layer of “high K” dielectric material in the remainder of the circuit.

1. An integrated circuit, comprising:
a substrate of a silicon-on-insulator type comprising a carrier substrate and a stack of a buried insulating layer and of a semiconductor film on top of the carrier substrate;
a first region wherein said stack is removed so as to separate a second region which includes said stack from a third region which also includes said stack; and
an MOS transistor having a gate dielectric region formed by a portion of the buried insulating layer of said stack in the second region, and having a gate region formed by a portion of the semiconductor film of said stack in the second region, and wherein at least a part of source and drain regions of the MOS transistor are provided within the carrier substrate.

2. The integrated circuit according to claim 1, wherein the first region comprises first and second separation regions which each respectively separate a face of the stack in the second region from a face of the stack in the third region, and wherein the source and drain regions of the MOS transistor comprise doped regions situated within the carrier substrate underneath said first and second separation regions, respectively.

3. The integrated circuit according to claim 2, wherein each of the first and second separation regions comprises an electrically-conducting region that contacts one of the doped regions and an insulating region disposed between the electrically-conducting region and the corresponding faces of the stacks of the second and third regions.

4. The integrated circuit according to claim 3, wherein each electrically-conducting region comprises an electrically-conducting contact.

5. The integrated circuit according to claim 3, wherein each electrically-conducting region comprises a semiconductor region.

6. The integrated circuit according to claim 2, wherein each separation region comprises:
a first isolation trench in contact with a first face of the stack of the second region, said first isolation trench extending into the carrier substrate,
a second isolation trench in contact with a first face of the stack of the third region, said second isolation trench extending into the carrier substrate, and
wherein the doped region of the corresponding source or drain region also extends, in part, into the portion of carrier substrate situated under the gate dielectric region of the transistor.

7. The integrated circuit according to claim 6, wherein each separation region further comprises an additional semiconductor region situated between the first isolation trench and the second isolation trench and covering the carrier substrate.

8. The integrated circuit according to claim 1, wherein a thickness of the buried insulating layer is in a range between around 12 nm and around 30 nm and a thickness of the semiconductor film is in a range between around 7 nm and around 10 nm.

9. The integrated circuit according to claim 1, wherein the substrate is of a fully-depleted silicon-on-insulator type.

10. The integrated circuit according to claim 1, furthermore comprising at least one other MOS transistor formed in and on a portion of the semiconductor film situated in the third region, said other MOS transistor having a gate dielectric region comprising a material with a high dielectric constant.

11. An integrated circuit, comprising:
a substrate of a silicon-on-insulator type comprising a carrier substrate and a stack of a buried insulating layer and of a semiconductor film on top of the carrier substrate;
a first separation region wherein said stack is removed;
a second separation region wherein said stack is removed;
wherein said first and second separation regions delimit a central region which includes said stack;
a first doped region in said carrier substrate under the central region;
a second doped region in said carrier substrate under the first separation region and forming a source region of a MOS transistor;
a third doped region in said carrier substrate under the second separation region and forming a drain region of said MOS transistor;
wherein a portion of the buried insulating layer of the stack in said central region forms a gate insulator region of said MOS transistor; and
wherein a portion of the semiconductor film of the stack in said central region forms a gate electrode of said MOS transistor.

12. The integrated circuit of claim 11,
wherein a portion of said second doped region extends under said portion of the buried insulating layer of the stack in said central region; and
wherein a portion of said third doped region extends under said portion of the buried insulating layer of the stack in said central region.

13. The integrated circuit of claim 11,
wherein the first doped region is of a first conductivity type; and
wherein the second and third doped regions are of a second, opposite, conductivity type.

14. The integrated circuit of claim 11, further comprising an insulating sidewall spacer on sidewalls of the stack for said central region.

15. The integrated circuit of claim 14, further comprising epitaxial material over said second and third doped regions which is isolated from said stack for said central region by said insulating sidewall spacer.

16. The integrated circuit of claim 11, further comprising an insulating trench on sidewalls of the stack for said central region, said insulating trench penetrating into each of the second and third doped regions.

17. The integrated circuit of claim 16, further comprising epitaxial material over said second and third doped regions which is isolated from said stack for said central region by said insulating trench.

18. The integrated circuit of claim 11, wherein said first doped region in said carrier substrate extends under the central region and the first and second separation regions.

19. The integrated circuit of claim 18, wherein the second and third doped regions are formed within the first doped region.
